(19) United States
(12) Patent Application Publication
(10) Pub. No.: US 2024/0354467 A1
(43) Pub. Date: Oct. 24, 2024

(54) COMPUTING DEVICE AND COMPUTING METHOD FOR A VIRTUAL ENVIRONMENT MEASUREMENT

(71) Applicant: DELTA ELECTRONICS, INC., Taoyuan City (TW)

(72) Inventors: Ren-Feng DING, Taoyuan City (TW); Keng-Ning CHANG, Taoyuan City (TW); Chia-Jun YU, Taoyuan City (TW)

(21) Appl. No.: 18/463,576

(22) Filed: Sep. 8, 2023

(30) Foreign Application Priority Data
Apr. 21, 2023 (CN) 202310435114.8

(51) Int. Cl. G06F 30/20; G01S 7/48; G01S 17/04; G01S 17/42

(52) U.S. Cl. CPC G06F 30/20; G01S 7/4808; G01S 17/04; G01S 17/42

(57) ABSTRACT

A computing device is disclosed to generate a virtual environment including a first virtual displacement sensor and a second virtual displacement sensor, load an object under detection into the virtual environment, make the first virtual displacement sensor send a first distance-measuring signal to the object under detection to compute a first distance between the first virtual displacement sensor and the object under detection, compute a clean distance between the second virtual displacement sensor and the object under detection based on the first distance and a first spacing, make the second virtual displacement sensor send a second distance-measuring signal to the object under detection to compute a second distance, determine that an obstacle exists between the object under detection and the second virtual displacement sensor when the second distance is less than the clean distance, and send a notification message to an electronic device.

### BACKGROUND OF THE DISCLOSURE

### Technical Field

The disclosure generally relates to a computing device and a computing method, and more particularly, to a computing device for simulating a simulated environment as if a measurement of a physical object is performed in a real environment.

### Description of Related Art

The product measurement process is an important procedure during research, development, and manufacturing. The product measurement process of the related art is, for example, to perform the high precision measurement on precision instruments by the laser light measurement technology, so the real shape of products can be presented.

In the product measurement process, when the pose of the product (e.g., related to the face or direction of the measurement device) is arbitrary or the product is put near an obstacle, the arrangement of measurement components of a measurement system and the measurement means affects obtained values and the accuracy of the result.

### SUMMARY OF THE DISCLOSURE

One of the exemplary embodiments of the present disclosure is to provide a computing device for virtual environment measurement, and the computing device includes an input-output module and a processor. The input-output module is configured to receive a control instruction. The processor is connected with the input-output module and configured to: generate a virtual environment including a first virtual displacement sensor and a second virtual displacement sensor, where the first virtual displacement sensor is spaced apart from the second virtual displacement sensor a first spacing; load an object under detection into the virtual environment, where the object under detection corresponds to a physical object in a real environment; make the first virtual displacement sensor send a first distance-measuring signal to the object under detection according to the control instruction to compute a first distance between the first virtual displacement sensor and the object under detection; compute a clean distance between the second virtual displacement sensor and the object under detection based on the first distance and the first spacing; make the second virtual displacement sensor send a second distance-measuring signal to the object under detection to compute a second distance; make a determination that an obstacle exists between the object under detection and the second virtual displacement sensor when the second distance is less than the clean distance; and send a notification message to an electronic device according to the determination that the obstacle exists between the object under detection and the second virtual displacement sensor.

One of the exemplary embodiments of the present disclosure is to provide a computing method for virtual environment measurement including generating a virtual environment including a first virtual displacement sensor and a second virtual displacement sensor, where the first virtual displacement sensor is spaced apart from the second virtual displacement sensor a first spacing; loading an object under detection into the virtual environment, where the object under detection corresponds to a physical object in a real environment; sending a first distance-measuring signal by the first virtual displacement sensor to the object under detection according to the control instruction that is inputted by a computing device to compute a first distance between the first virtual displacement sensor and the object under detection; computing a clean distance between the second virtual displacement sensor and the object under detection based on the first distance and the first spacing; sending a second distance-measuring signal by the second virtual displacement sensor to the object under detection to compute a second distance; making a determination that an obstacle exists between the object under detection and the second virtual displacement sensor when the second distance is less than the clean distance; and sending a notification message to the computing device according to the determination that the obstacle exists between the object under detection and the second virtual displacement sensor.

### BRIEF DESCRIPTION OF THE DRAWINGS

FIG. 1 illustrates a schematic diagram that a computing device and a physical object are disposed in a real environment.

FIG. 2 is another schematic diagram illustrating that the computing device and the physical object are disposed in the real environment.

FIG. 3 is a block diagram illustrating a computing device in accordance with one embodiment of the present disclosure.

FIG. 4 is a flow chart illustrating a computing method for measuring in a virtual environment in accordance with one embodiment of the present disclosure.

FIG. 5 illustrates an example virtual environment simulated by the computing device in accordance with one embodiment of the present disclosure.

FIG. 6 illustrates an example virtual environment simulated by the computing device in accordance with one embodiment of the present disclosure.

FIG. 7 illustrates an example virtual environment simulated by the computing device in accordance with one embodiment of the present disclosure.

FIG. 8 is a flow chart illustrating a computing method for measuring in a virtual environment in accordance with another embodiment of the present disclosure.

FIG. 9 illustrates an example virtual environment simulated by the computing device in accordance with one embodiment of the present disclosure.

FIG. 10 illustrates an example virtual environment simulated by the computing device in accordance with one embodiment of the present disclosure.

### DETAILED DESCRIPTION

The technical terms “first”, “second”, and the similar terms are used to describe elements for distinguishing the same or similar elements or operations and are not intended to limit the technical elements and the order of the operations in the present disclosure. Furthermore, the element symbols/alphabets can be used repeatedly in each embodiment of the present disclosure. The same and similar technical terms can be represented by the same or similar symbols/alphabets in each embodiment. The repeated symbols/alphabets are provided for simplicity and clarity and they should not be interpreted to limit the relation of the technical terms among the embodiments.

Reference will now be made in detail to the present embodiments of the disclosure, examples of which are illustrated in the accompanying drawings. Wherever possible, the same reference numbers are used in the drawings and the description to refer to the same or like parts.

The present disclosure provides operations of computing a relevant distance between virtual sensors and an object under detection and an inclined angle of the virtual environment in a virtual environment, and the information is applied to detect whether the object under detection is defective based on the information. Specifically, software programs may be applied in the present disclosure to build the virtual environment based on the conditions of a real environment, so the virtual environment acts as the real environment. On the other hand, the physical object in the real environment is an object that is to be detected. For this purpose, a modeling method is built to simulate an object under detection in the virtual environment, so the object under detection is operable in the virtual environment. The computation technique provided in the present disclosure performs relevant operations to the object under detection in the virtual environment and obtains computation results. The computation results are applied to assess problems or the defects of the physical object in the real environment.

It should be noted that the conditions of the real environment are more complicated than those of the virtual environment, so the complexity of the software design affects the level of presenting the real environment.

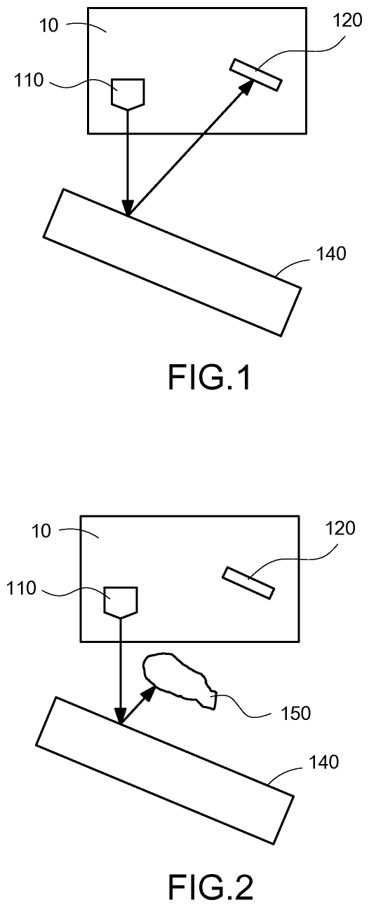

Reference is made to FIG. 1. FIG. 1 illustrates a schematic diagram that a computing device and a physical object are disposed in a real environment. The computing device 10 includes a light-emitting module 110 and a sensor 120. The light-emitting module 110 emits light toward a physical object 140, and the sensor 120 receives reflected light from the physical object 140 and computes a distance between the computing device 10 and the physical object 140 based on a strength of the reflected light (e.g., the light-emitting module 110 emits the light and the light hits a light point on the physical object 140, where the distance between the computing device 10 and the physical object 140 is the distance between the light point and a shield of the computing device 10).

Reference is made to FIG. 2. FIG. 2 is another schematic diagram illustrating that the computing device and the physical object are disposed in the real environment. In the embodiment of FIG. 2, if an obstacle 150 exists between the physical object 140 and the sensor 120, the reflected light may be blocked by the obstacle 150 that results in the sensor 120 being incapable of receiving the reflected light, so the distance between the computing device 10 and the physical object 140 cannot be measured.

On the other hand, the reflected light in FIG. 1 and FIG. 2 is the physical phenomenon only happened in the real environment, so it might be a question of whether the reflected light effect is correctly simulated and implemented in the virtual environment. Accordingly, the present disclosure provides a computing device and a computing method to simulate the virtual environment with operation effects the same as the real environment without simulating the reflected light. Not only is the relevant distance between the virtual sensor and the object under detection in the virtual environment correctly computed, the obstacle between the virtual sensor and the object under detection is also detected. Therefore, the correctness of detecting the object is improved.

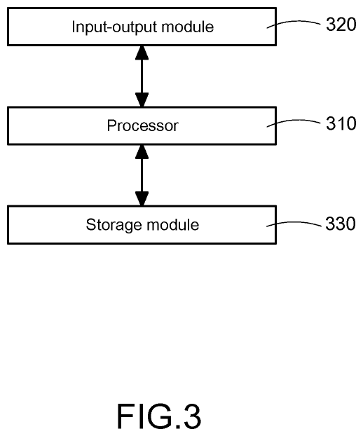

Reference is made to FIG. 3. FIG. 3 is a block diagram illustrating a computing device in accordance with one embodiment of the present disclosure. The computing device includes a processor 310, an input-output module 320, and a storage module 330. The processor 310 is connected with the input-output module 320 and the storage module 330.

In one embodiment, the storage module 330 stores a plurality of program codes. When the plurality of program codes is loaded into the processor 310, the processor 310 executes the program codes to simulate a virtual environment and virtual objects. The virtual environment includes an environment model of a virtual three-dimensional space. The virtual objects include virtual displacement sensors being executable functions the same as the physical displacement sensors. For the sake of brevity, the program codes for simulating the virtual displacement sensors are not listed herein.

In another embodiment, the processor 310 executes the program codes (e.g., the three-dimensional modeling software) to simulate the object under detection indicating the physical object and being operable in the virtual environment, so the operating conditions of the object under detection in the virtual environment are same as the physical characteristics of the physical object in the real environment.

It should be noted that in the disclosure the technical term “object under detection” indicates the virtual object in the virtual environment; the technical term “light beam” indicates a virtual light beam simulated in the virtual environment and used for measuring distances. When the light beam (the virtual light beam) is projected onto the object under detection (the virtual object), a light point is presented on the object under detection (e.g., the intersection point that the virtual light beam hits on a surface of the virtual object).

In one embodiment, the input-output module 320 is configured to receive a control instruction, such as operating parameters of the virtual environment and the virtual objects.

In one embodiment, the processor 310 may be, but not limited to, a Digital Signal Processor (DSP), an Application Specific Integrated Circuit (ASIC), a Central Processing Unit (CPU), a System on Chip (SoC), a Field Programmable Gate Array (FPGA), or a Network Processor IC.

In one embodiment, the input-output module 320 may be, but not limited to, a keyboard, a mouse, a touch screen, a microphone (the input device), a monitor, a speaker, or an indicating light (the output device).

In one embodiment, the storage module 330 may be, but not limited to, a Random Access Memory (RAM), a nonvolatile memory (such as flash memory), a Read-Only Memory (ROM), a Hard Disk Drive (HDD), a Solid-State Drive (SSD), or an Optical Storage.

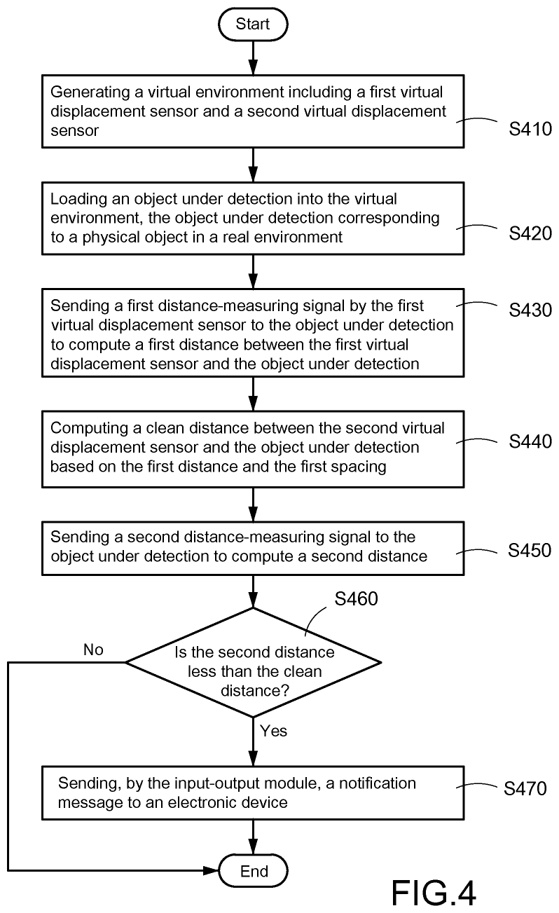

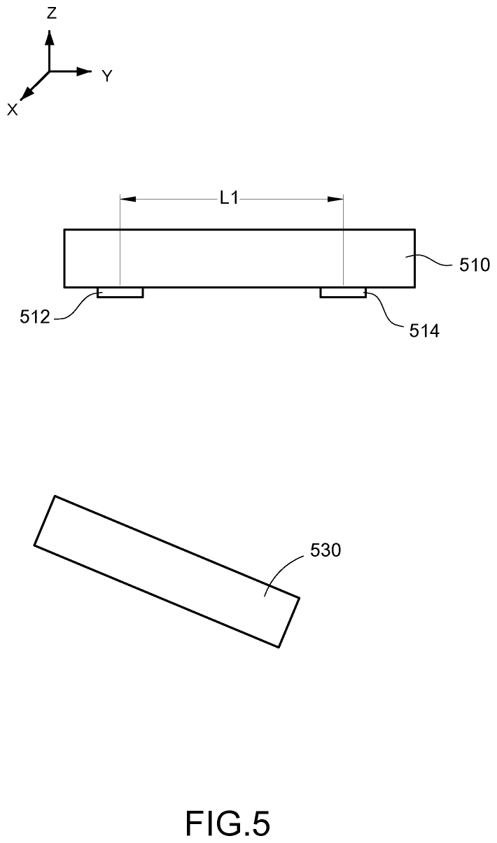

Reference is made to FIG. 4. FIG. 4 is a flow chart illustrating a computing method for measuring in a virtual environment in accordance with one embodiment of the present disclosure. For showing steps of the computing method for the virtual environment measurement performed by the computing device, FIG. 4 and FIG. 5 are incorporated with the statement below. FIG. 5 illustrates an example virtual environment simulated by the computing device in accordance with one embodiment of the present disclosure. The computing device in FIG. 3 performs the computing method for the virtual environment measurement in FIG. 4, and the steps in FIG. 4 are performed by the virtual objects in the virtual environment.

In step S410, the computing device generates the virtual environment including a first virtual displacement sensor and a second virtual displacement sensor.

In FIG. 5, the virtual environment includes a virtual sensing module 510, and the virtual sensing module 510 includes a first virtual displacement sensor 512 and a second virtual displacement sensor 514.

In one embodiment, there is a spacing L1 (a first spacing) between the first virtual displacement sensor 512 and the second virtual displacement sensor 514.

The first virtual displacement sensor 512 and the second virtual displacement sensor 514 are the virtual objects simulated by the computing device with functions the same as the physical displacement sensors, so these virtual objects may perform the computation of measuring distances. For example, the first virtual displacement sensor 512 (and the second virtual displacement sensor 514) may emit a virtual light beam to a target object and execute an algorithm to obtain the light point on the target object (i.e., the intersection point of the virtual light beam and the surface of the target object), so the distance between the virtual sensing module 510 and the target object (e.g., the straight line distance between a coordinate of the first virtual displacement sensor 512 and a coordinate of the intersection point) may be obtained. It should be noted that the algorithms for computing the distance are not limited herein.

In step S420, the object under detection 530 is loaded into the virtual environment, wherein the object under detection 530 being loaded is corresponding to the physical object in the real environment.

In one embodiment, the object under detection 530 is the virtual object generated by the three-dimensional modeling, so the operations and the conditions of the object under detection 530 in the virtual environment are the same as the physical characteristics of the physical object in the real environment.

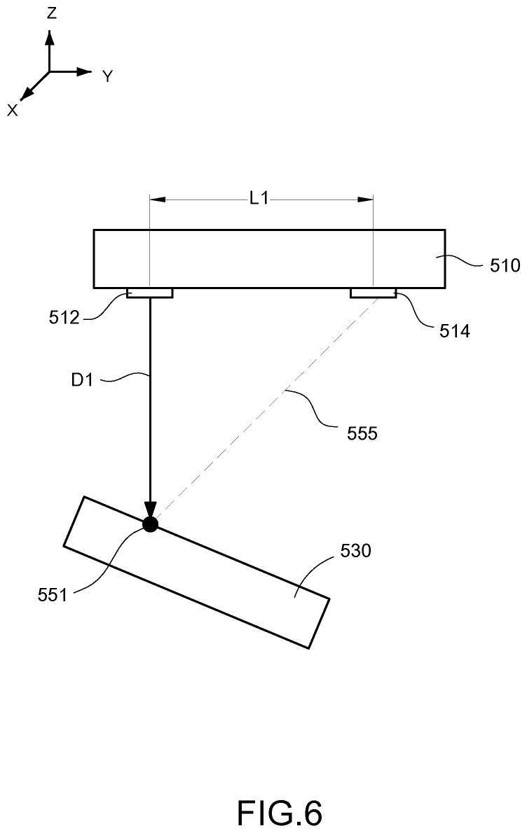

Further statements of step S430 and step S440 are made incorporated with FIG. 6. FIG. 6 illustrates an example virtual environment simulated by the computing device in accordance with one embodiment of the present disclosure.

In step S430, the first virtual displacement sensor 512 sends a first distance-measuring signal to the object under detection 530 to compute a first distance D1 between the first virtual displacement sensor 512 and the object under detection 530.

In one embodiment, the first distance-measuring signal sent by the first virtual displacement sensor 512 is the light beam (the virtual light beam). The light beam is projected onto the light point 551 of the object under detection 530 and reflects a reflection signal at the light point 551 to the first virtual displacement sensor 512. The first virtual displacement sensor 512 computes the first distance D1 between the first virtual displacement sensor 512 and the object under detection 530 (at the light point 551) according to the reflection signal.

In step S440, the computing device computes a clean distance 555 between the second virtual displacement sensor 514 and the object under detection 530 based on the first distance D1 and the first spacing L1.

In one embodiment, a direction of the light beam sent by the first virtual displacement sensor 512 is perpendicular to the plane of the first virtual displacement sensor 512 and the second virtual displacement sensor 514 (e.g., the X-Y plane). Because the first spacing L1 is a known information and the computing device may receive the value of the first distance D1 after step S430, the clean distance 555 between the second virtual displacement sensor 514 and the object under detection 530 is computed based on the Pythagorean theorem.

In one embodiment, the clean distance 555 is the distance between the second virtual displacement sensor 514 and the light point 551 of the object under detection 530.

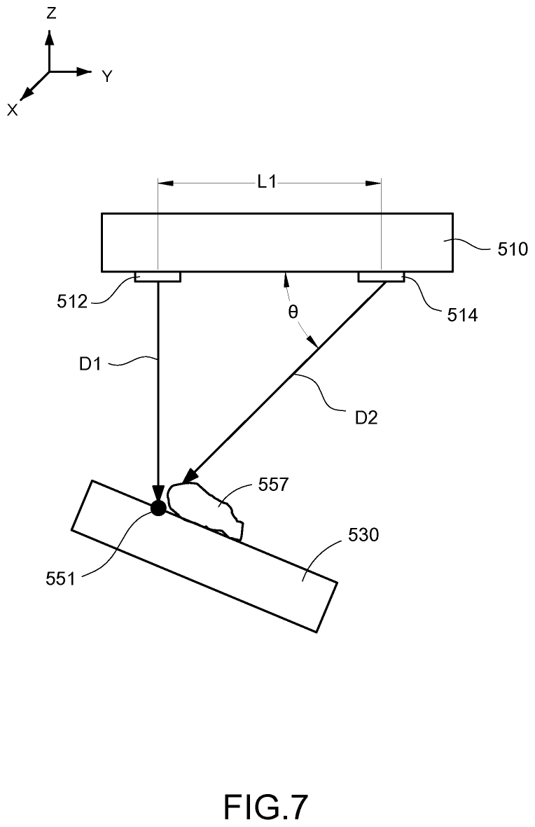

Further statements of step S450 are made incorporated with FIG. 7. FIG. 7 illustrates an example virtual environment simulated by the computing device in accordance with one embodiment of the present disclosure.

In step S450, the second virtual displacement sensor 514 sends a second distance-measuring signal toward the light point 551 of the object under detection 530 to compute a second distance D2.

In one embodiment, before the second virtual displacement sensor 514 sends the second distance-measuring signal, the computing device computes the arc tangent function tan⁻¹(D1/L1) to obtain an intersection angle θ (in FIG. 7) between a straight line formed by the first virtual displacement sensor 512 and the second virtual displacement sensor 514 and the straight line formed by the second virtual displacement sensor 514 and the light point 551.

The computing device controls a direction that the second virtual displacement sensor 514 emits the light beam according to the intersection angle θ, so the second virtual displacement sensor 514 emits the light beam to an indicated position to compute the distance between the indicated position and the second virtual displacement sensor 514.

In one embodiment, the computing device adjusts the emission angle that the second virtual displacement sensor 514 emits the light beam based on the intersection angle θ. For example, a default emission direction of the second virtual displacement sensor 514 is perpendicular to the plane of the first virtual displacement sensor 512 and the second virtual displacement sensor 514 (e.g., the X-Y plane), then the emission direction of the second virtual displacement sensor 514 is adjusted by being rotated by an angle (90°−θ) in a clockwise direction.

After the emission direction of the second virtual displacement sensor 514 is adjusted, the second virtual displacement sensor 514 sends the second distance-measuring signal to the object under detection 530 in the adjusted emission direction. In the meantime, the second virtual displacement sensor 514 computes the distance (i.e., the second distance D2). In one embodiment, the second virtual displacement sensor 514 sends the second distance-measuring signal toward the light point 551 of the object under detection 530 according to the adjusted emission direction. In this case, the second distance D2 is the straight-line distance between the coordinate of the second virtual displacement sensor 514 and the coordinate of the light point 551, when no obstacle exists (detailed described in the following).

It should be noted that the value of the second distance D2 is different from the actual situation of the object under detection. For example, when an obstacle 557 (e.g., a speck of dirt or an unexpected deformation of the object under detection 530) exists on the surface of the object under detection 530 or between the object under detection 530 and the second virtual displacement sensor 514, the second distance-measuring signal sent by the second virtual displacement sensor 514 is projected on the obstacle 557 instead of the surface of the object under detection 530. In this case, the second distance D2 computed by the second virtual displacement sensor 514 is less than the clean distance 555 (in FIG. 6 and FIG. 7).

On the other hand, when the obstacle 557 does not exist on the surface of the object under detection 530 or between the object under detection 530 and the second virtual displacement sensor 514, the second distance-measuring signal sent by the second virtual displacement sensor 514 is projected on the object under detection 530.

Reference is made back to FIG. 4. In step S460, the computing device determines whether the second distance D2 is less than the clean distance 555.

In step S460, when the computing device determines that the second distance D2 is less than the clean distance 555, step S470 is performed. When the computing device determines that the second distance D2 is not less than the clean distance 555, the process is finished. In step S470, the computing device sends, by the input-output module 120, a notification message to the electronic device.

As mentioned above, when the second distance D2 is less than the clean distance 555, the computing device determines that the obstacle 557 (FIG. 7) exists on the surface of the object under detection 530 or between the object under detection 530 and the second virtual displacement sensor 514. In this case, the computing device sends a notification to the administrator about the event of the bad quality of the object under detection 530 or other unexpected results. Therefore, the administrator adjusts the physical object in the real environment based on the computation result of the computing device.

In one embodiment, the electronic device may be, but not limited to, a tablet computer, a notebook computer, a personal computer, a wearable computer (e.g., a pair of smart glasses, a virtual reality head-mounted device, or a smartwatch), or an electronic device having a processor and/or a storage device executing applications installed thereon and/or on a cloud server.

In another embodiment, the object under detection may be inclined. The present disclosure provides the computing device and the computing method that determine whether the object under detection is inclined and compute an inclined angle of the object under detection.

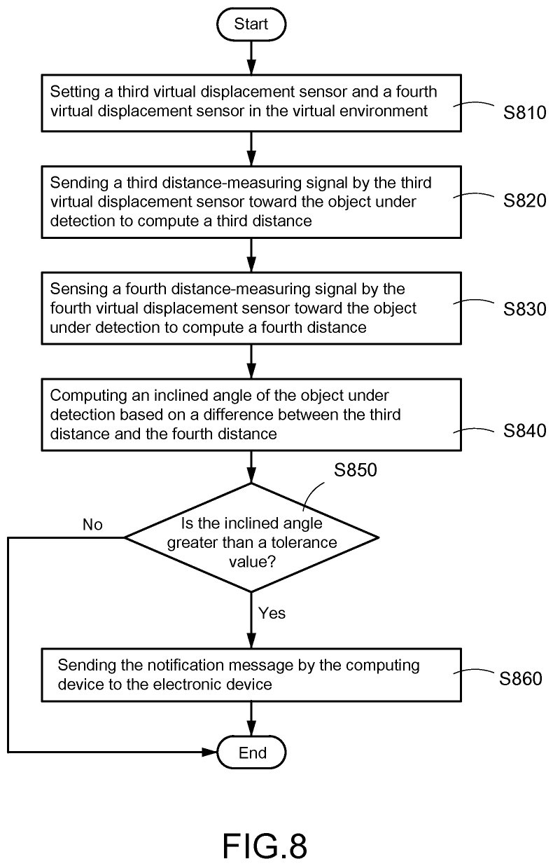

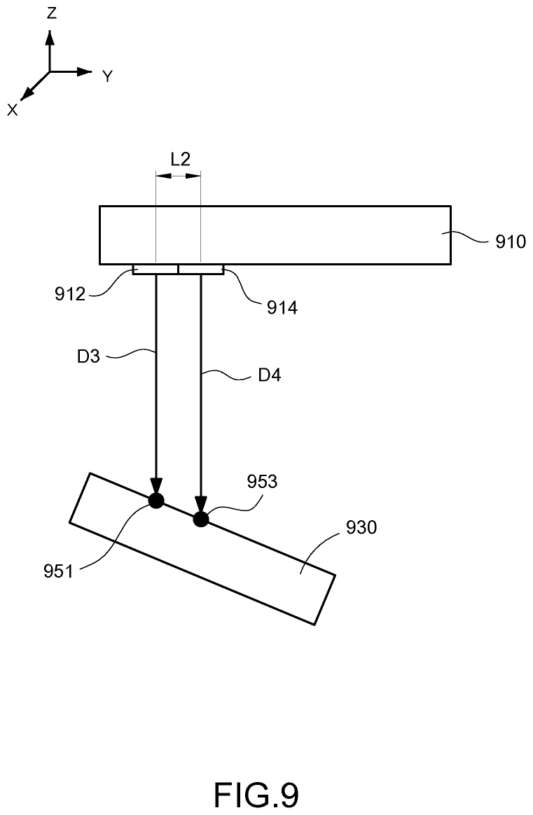

Reference is made to FIG. 8. FIG. 8 is a flow chart illustrating a computing method for measuring in a virtual environment in accordance with another embodiment of the present disclosure. The computing device in FIG. 3 performs the computing method for the virtual environment measurement in FIG. 8 and controls the virtual objects in the virtual environment to perform steps in FIG. 8. For showing steps of the computing method for the virtual environment measurement performed by the computing device, FIG. 8 and FIG. 9 are incorporated with the statement below. FIG. 9 illustrates an example virtual environment simulated by the computing device in accordance with one embodiment of the present disclosure.

In step S810, the computing device generates and sets a third virtual displacement sensor 912, and a fourth virtual displacement sensor 914 in the virtual environment.

As shown in FIG. 9, the virtual environment includes a virtual sensing module 910, and the virtual sensing module 910 includes the third virtual displacement sensor 912 and the fourth virtual displacement sensor 914. Similar to the statement above, the third virtual displacement sensor 912, and the fourth virtual displacement sensor 914 are the virtual objects simulated by the computing device with the functions same as the physical displacement sensors, so the virtual objects also perform the computation method for the distance computation.

In one embodiment, there is a spacing L2 (i.e., the second spacing) between the third virtual displacement sensor 912 and the fourth virtual displacement sensor 914. The third virtual displacement sensor 912 shifts the spacing L2 from the fourth virtual displacement sensor 914 in the Y direction.

In one embodiment, the spacing L2 is the distance between the emitting points of the light beams respectively emitted by the third virtual displacement sensor 912 and the fourth virtual displacement sensor 914 after the third virtual displacement sensor 912 and the fourth virtual displacement sensor 914 are arranged to closely adjoin or adjacent to each other. Because the virtual environment is the computation environment simulated by the computing device, the administrator may set a length of the spacing L2 based on the designed measurement condition.

In step S820, the third virtual displacement sensor 912 sends a third distance-measuring signal toward the object under detection 930 to compute a third distance D3 between the third virtual displacement sensor 912 and the object under detection 930.

In the embodiment of FIG. 9, the light beam of the third virtual displacement sensor 912 is projected to a light point 951 of the object under detection 930, and the third distance D3 is the straight-line distance between a coordinate of the light point 951 and a coordinate of the emitting point of the third virtual displacement sensor 912.

In step S830, the fourth virtual displacement sensor 914 sends a fourth distance-measuring signal toward the object under detection 930 to compute a fourth distance D4 between the fourth virtual displacement sensor 914 and the object under detection 930.

In the embodiment of FIG. 9, the light beam of the fourth virtual displacement sensor 914 is projected to a light point 953 of the object under detection 930, and the fourth distance D4 is the straight-line distance between a coordinate of the light point 953 and a coordinate of the emitting point of the fourth virtual displacement sensor 914.

In the embodiment of FIG. 9, emission angles of the light beams emitted by the third virtual displacement sensor 912 and the fourth virtual displacement sensor 914 are perpendicular to the plane of the third virtual displacement sensor 912 and the fourth virtual displacement sensor 914 (e.g., the X-Y plane). In other words, the light beams emitted by the third virtual displacement sensor 912 and the fourth virtual displacement sensor 914 are parallel with each other.

In step S840, the computing device computes an inclined angle of the object under detection 930 based on a difference between the third distance D3 and the fourth distance D4 and the second spacing L2.

In one embodiment, because the spacing between the third virtual displacement sensor 912 and the fourth virtual displacement sensor 914 (i.e., the x-coordinates and the z-coordinates of the two sensors are the same and the difference of the y-coordinates Δy is the spacing L2) is the spacing L2 and the spacing between the third distance D3 and the fourth distance D4 is the difference Δx in the X direction, the difference Δx may represent the inclined state by rotating around the X-axis. Therefore, the computing device applies the difference between the third distance D3 and the fourth distance D4, the spacing L2, and the arc tangent function to compute the inclined angle of the object under detection 930 relevant to rotating around the X-axis in the virtual three-dimensional space.

In one embodiment, an imaginary line (i.e., a first straight line) (not shown in figures) is formed by the light point 951 and the light point 953 on the object under detection 930, another imaginary line (i.e., a second straight line) (not shown in figures) is formed by the third virtual displacement sensor 912 and the fourth virtual displacement sensor 914. The inclined angle is the intersection angle formed by the first straight line and the second straight line, that is, the virtual sensing module 910 is a reference line, and the object under detection 930 shifts an angle based on the virtual sensing module 910.

In step S850, the computing device determines whether the inclined angle is greater than a tolerance value. When the inclined angle is greater than the tolerance value, step S860 is performed. When the inclined angle is not greater than the tolerance value, the process is finished.

In step S860, the computing device sends a notification message by the input-output module 120 to the electronic device to inform the administrator about the abnormal situation of the inclined angle of the object under detection 930. Therefore, the administrator may adjust the physical object in the real environment to prevent the problem that the inclined angle of the physical object is so large that affects the normal detection or the product processing.

It should be noted that the physical displacement sensor has a physical minimal size in the real environment, so there is a minimum spacing between two adjacent physical displacement sensors and the minimal spacing is a physically adjacent-limit distance (a physically closest distance) between the two physical displacement sensors, where the actual value of the physically adjacent-limit distance depends on the volume of the electronic components and the physical configuration requirement. For example, after the electronic components are welded to a circuit board, there is a spacing between the electronic components due to the welding.

Because the physically adjacent-limit distance exists in the real environment, two physical displacement sensors may not be very close to each other (such as 1 millimeter). For some kinds of electronic components (such as the integrated circuit), the minimal spacing between two physical displacement sensors may not meet the requirement for measurement. Therefore, when the computing method in FIG. 8 is applied to the two physical displacement sensors of the real environment to measure the inclined angle of the physical object, the light beams emitted by the two physical displacement sensors may hit on different physical objects or different surfaces of the same physical object that leads to an error computation result.

In one embodiment, because the virtual environment is the computation environment simulated by the computing device, the spacing L2 between the third virtual displacement sensor 912 and the fourth virtual displacement sensor 914 may be set less than the physically adjacent-limit distance between the physical displacement sensors.

As mentioned above, the light beams emitted by the third virtual displacement sensor 912 and the fourth virtual displacement sensor 914 are parallel and very close to each other (such as less than 1 millimeter), so the light points 951 and 953 are also very closed to each other. In this case, the probability that the obstacle appears between the two close points is extremely small and the probability that the two close points are at two different objects under detection is also extremely small, so the present disclosure may ensure that the two light beams are emitted on the same surface of the same object under detection 930 instead of on different objects under detection 930, different planes of the same object under detection 930, or the obstacle adjacent to the object under detection 930.

Furthermore, the third distance D3 is the distance between the third virtual displacement sensor 912 and the object under detection 930, the fourth distance D4 is the distance between the fourth virtual displacement sensor 914 and the object under detection 930, and the two light beams respectively emitted by the two sensors 912 and 914 are parallel, so the third distance D3 and the fourth distance D4 may reflect the real inclined situation of the object under detection 930 and the computation result of the inclined angle of the object under detection 930 may be correctly obtained. Accordingly, the accuracy of computing the inclined angle is increased.

Compared with the statement above, because the physical displacement sensors of the real environment cannot be disposed as close as the statement above that the virtual displacement sensors are very close to each other, two distances obtained by the two physical displacement sensors cannot reflect the real inclined situation of the object under detection, so the computation result of the inclined angle is not accurate.

It should be noted that the virtual environment in FIG. 5 does not restrict the spacing (i.e., the first spacing L1) between the first virtual displacement sensor 512 and the second virtual displacement sensor 514, so the administrator may set the suitable value of the first spacing L1 based on the actual measurement condition, and the first spacing L1 is not restricted whether being less than physically adjacent-limit distance or not.

On the other hand, as mentioned above, in FIG. 9 the spacing between the third virtual displacement sensor 912 and the fourth virtual displacement sensor 914 (i.e., the second spacing L2) must be very small (i.e., the two sensors must be very close to each other), so the second spacing L2 is less than the first spacing L1 and the physically adjacent-limit distance.

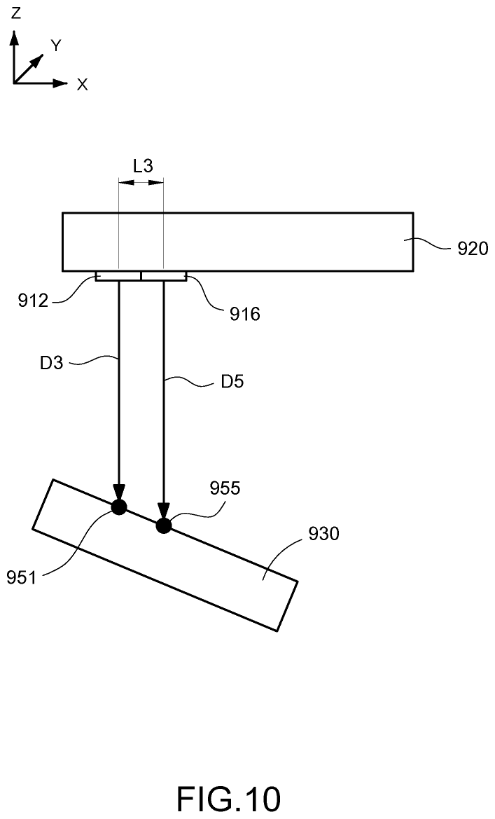

Reference is made to FIG. 10. FIG. 10 illustrates an example virtual environment simulated by the computing device in accordance with one embodiment of the present disclosure. The computing device in FIG. 3 is configured to perform the computing method for the virtual environment measurement in FIG. 8 and generate the virtual environment and the virtual object in FIG. 10. The virtual environment includes a virtual sensing module 920, and the virtual sensing module 920 includes a third virtual displacement sensor 912 and a fifth virtual displacement sensor 916. Similar to the statement above, the fifth virtual displacement sensor 916 is the virtual object simulated by the computing device with the functions same as the physical displacement sensor, so the virtual objects also perform the computation method for the distance computation.

In one embodiment, a spacing L3 (third spacing) exists between the third virtual displacement sensor 912 and the fifth virtual displacement sensor 916. The third virtual displacement sensor 912 shifts the spacing L3 in the X-direction from the fifth virtual displacement sensor 916.

The embodiment of FIG. 10 is similar to that of FIG. 9, that is, the coordinate system in FIG. 10 is the coordinate system in FIG. 9 rotated 90 degrees counterclockwise along Z-axis. The emission angles of the light beams emitted by the third virtual displacement sensor 912 and the fifth virtual displacement sensor 916 are perpendicular to the X-Y plane.

In one embodiment, the computing device performs the computing method in FIG. 8 and replaces the fourth virtual displacement sensor 914 with the fifth virtual displacement sensor 916 in the computing method to obtain a fifth distance D5. Because the distance between the third virtual displacement sensor 912 and the fifth virtual displacement sensor 916 is the spacing L3 (that is, the y-coordinate and the z-coordinate of the two sensors are the same, so the difference value of the x-coordinate Δx between the two sensors is the spacing L3) and the distance between the third distance D3 and the fifth distance D5 is the difference value Δy in the Y direction, the difference value Δy may present the inclined condition in the Y-axis. Therefore, the computing device applies the difference value Δy between the third distance D3 and the fifth distance D5, the spacing L3, and the arc tangent function to compute the inclined angle of the object under detection 930 in the virtual three-dimensional space, where the inclined angle is reflected based on the Y-axis.

In one embodiment, the computing device uses the coordinates of the light points 951, 953, and 955 that the third virtual displacement sensor 912, the fourth virtual displacement sensor 914, and the fifth virtual displacement sensor 916 project on the object under detection 930 in FIG. 9 and FIG. 10 to compute a plane inclined angle between the plane of the object under detection 930 and the plane of the X-Y plane.

In one embodiment, in step S850 of FIG. 8, the computing device determines whether the plane inclined angle is greater than the tolerance value and the determination is used to send the notification message to the electronic device.

Similarly, the computing device may also measure the plane inclined angle between the plane of the object under detection 930 and the X-Z plane or the Y-Z in the virtual three-dimensional space. For the sake of brevity, the statement is not repeated.

In one embodiment, the third virtual displacement sensor 912 in FIG. 9 and the first virtual displacement sensor 512 in FIG. 5 may be the same virtual displacement sensor. In the embodiment, the computing device sets four virtual displacement sensors (i.e., the first virtual displacement sensor 512, the second virtual displacement sensor 514, the fourth virtual displacement sensor 914, and the fifth virtual displacement sensor 916) in the virtual environment. The four virtual displacement sensors are configured to detect whether the obstacle exists on or near the object under detection and measure the inclined angle of the object under detection. It should be noted that the quantity of the virtual displacement sensors set in the virtual environment is not limited and any quantity may be applied based on the actual condition.

In one embodiment, the computing method in FIG. 4 and FIG. 8 may be implemented as a computer program and stored in a non-transitory computer-readable storage medium. The computing device or a computer reads the storage medium to perform each step of the computing method.

Accordingly, the computing device and the computing method for the virtual environment measurement provided in the present disclosure are implemented by at least two virtual displacement sensors in the virtual environment to simulate the function for measuring the object under detection as if the object under detection was measured in the real environment, and the measurement function same in the real environment may be performed without designing the physical condition of the real environment. Therefore, the implementation of the present disclosure may reduce the design complexity and implement the measurement with lower hardware costs.

Furthermore, the computing device and the computing method in the present disclosure solve the problem that the physical displacement sensors in the real environment are incapable of being close enough to each other to perform accurate measurement. Because the virtual displacement sensors of the present disclosure are close enough, the computing method may ensure the two light points respectively emitted by the two virtual displacement sensors are on the same plane of the object under detection instead of on an unknown obstacle. Therefore, the inclined angle of the object under detection is accurately measured.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A computing device for virtual environment measurement, comprising:
an input-output module, configured to receive a control instruction; and
a processor, connected with the input-output module and configured to:
generate a virtual environment comprising a first virtual displacement sensor and a second virtual displacement sensor, wherein the first virtual displacement sensor is spaced apart from the second virtual displacement sensor a first spacing;
load an object under detection into the virtual environment, wherein the object under detection corresponds to a physical object in a real environment;
make the first virtual displacement sensor send a first distance-measuring signal to the object under detection according to the control instruction to compute a first distance between the first virtual displacement sensor and the object under detection;
compute a clean distance between the second virtual displacement sensor and the object under detection based on the first distance and the first spacing;
make the second virtual displacement sensor send a second distance-measuring signal to the object under detection to compute a second distance;
make a determination that an obstacle exists between the object under detection and the second virtual displacement sensor when the second distance is less than the clean distance; and
send a notification message to an electronic device according to the determination that the obstacle exists between the object under detection and the second virtual displacement sensor.

2. The computing device of claim 1, wherein the processor is configured to make the first virtual displacement sensor send the first distance-measuring signal to the object under detection to make a reflection signal be reflected at a light point on the object under detection and make the first virtual displacement sensor compute the first distance according to the reflection signal.

3. The computing device of claim 2, wherein the clean distance is a distance between the second virtual displacement sensor and the light point.

4. The computing device of claim 3, wherein the processor is configured to:
adjust an emission angle of the second virtual displacement sensor based on an intersection angle between a straight line formed by the first virtual displacement sensor and the second virtual displacement sensor and another straight line formed by the second virtual displacement sensor and the light point; and
make the second virtual displacement sensor send the second distance-measuring signal to the light point on the object under detection according to the emission angle.

5. The computing device of claim 1, wherein the processor is configured to:
generate a third virtual displacement sensor and a fourth virtual displacement sensor in the virtual environment, wherein a second spacing between the third virtual displacement sensor and the fourth virtual displacement sensor is less than a physically adjacent-limit distance between two physical displacement sensors in the real environment.

6. The computing device of claim 5, wherein the processor is configured to:
make the third virtual displacement sensor send a third distance-measuring signal toward the object under detection and compute a third distance;
make the fourth virtual displacement sensor send a fourth distance-measuring signal toward the object under detection and compute a fourth distance, wherein a direction that the fourth distance-measuring signal is emitted is parallel to another direction that the third distance-measuring signal is emitted;
compute an inclined angle of the object under detection based on a difference between the third distance and the fourth distance; and
make the input-output module send the notification message to the electronic device when the inclined angle is greater than a tolerance value.

7. A computing method for virtual environment measurement, comprising:
generating a virtual environment comprising a first virtual displacement sensor and a second virtual displacement sensor, wherein the first virtual displacement sensor is spaced apart from the second virtual displacement sensor a first spacing;
loading an object under detection into the virtual environment, wherein the object under detection corresponds to a physical object in a real environment;
sending a first distance-measuring signal by the first virtual displacement sensor to the object under detection according to a control instruction that is inputted by a computing device to compute a first distance between the first virtual displacement sensor and the object under detection;
computing a clean distance between the second virtual displacement sensor and the object under detection based on the first distance and the first spacing;
sending a second distance-measuring signal by the second virtual displacement sensor to the object under detection to compute a second distance;
making a determination that an obstacle exists between the object under detection and the second virtual displacement sensor when the second distance is less than the clean distance; and
sending a notification message to the computing device according to the determination that the obstacle exists between the object under detection and the second virtual displacement sensor.

8. The computing method of claim 7, wherein step of computing the first distance between the first virtual displacement sensor and the object under detection comprises:
sending the first distance-measuring signal by the first virtual displacement sensor to the object under detection to make a reflection signal be reflected at a light point on the object under detection; and
computing the first distance according to the reflection signal.

9. The computing method of claim 8, wherein the clean distance is a distance between the second virtual displacement sensor and the light point.

10. The computing method of claim 9, before step of sending the second distance-measuring signal by the second virtual displacement sensor to the object under detection, further comprising:
adjusting an emission angle of the second virtual displacement sensor based on an intersection angle between a straight line formed by the first virtual displacement sensor and the second virtual displacement sensor and another straight line formed by the second virtual displacement sensor and the light point;
wherein the second virtual displacement sensor sends the second distance-measuring signal to the light point on the object under detection according to the emission angle.

11. The computing method of claim 7, further comprising:
generating a third virtual displacement sensor and a fourth virtual displacement sensor in the virtual environment, wherein a second spacing between the third virtual displacement sensor and the fourth virtual displacement sensor is less than a physically adjacent-limit distance between two physical displacement sensors in the real environment.

12. The computing method of claim 11, further comprising:
sending a third distance-measuring signal by the third virtual displacement sensor toward the object under detection to compute a third distance;
sending a fourth distance-measuring signal by the fourth virtual displacement sensor toward the object under detection to compute a fourth distance, wherein a direction that the fourth distance-measuring signal is emitted is parallel to another direction that the third distance-measuring signal is emitted;
computing an inclined angle of the object under detection based on a difference between the third distance and the fourth distance; and
sending the notification message by the computing device when the inclined angle is greater than a tolerance value.
